(19) United States
(12) Patent Application Publication
(10) Pub. No.: US 2014/0353834 A1
(43) Pub. Date: Dec. 4, 2014

(54) SEMICONDUCTOR DEVICE

(71) Applicant: TOYOTA JIDOSHA KABUSHIKI KAISHA, Toyota-shi, (JP)

(72) Inventors: Satoshi HIROSE, Toyota-shi (JP); Masaki AOSHIMA, Toyota-shi (JP); Hisashi ISHIMABUSHI, Toyota-shi (JP)

(73) Assignee: TOYOTA JIDOSHA KABUSHIKI KAISHA, Toyota-shi (JP)

(21) Appl. No.: 14/284,801

(22) Filed: May 22, 2014

(30) Foreign Application Priority Data
Jun. 3, 2013 (JP) 2013-116647

(51) Int. Cl. H01L 23/373; H01L 23/498

(52) U.S. Cl. CPC H01L 23/3736; H01L 23/498
USPC 257/772

(57) ABSTRACT

A semiconductor device includes a first electrode, a second electrode, and an endothermic layer. The first electrode, the second electrode and the endothermic layer are formed on a semiconductor substrate. The first electrode is electrically conductive with an element formed inside of the semiconductor substrate. The endothermic layer is in contact with the first electrode and has electric conductivity. The second electrode is in contact with at least one of the first electrode and the endothermic layer and soldered to a metal electric conductor. Herein, at least one of a work function and contact resistivity of the first electrode is smaller than that of the endothermic layer. A heat of melting of the endothermic layer is larger than that of the first electrode. Solder joinability of the second electrode is higher than that of the endothermic layer.

### INCORPORATION BY REFERENCE

The disclosure of Japanese Patent Application No. 2013-116647 filed on Jun. 3, 2013 including the specification, drawings and abstract is incorporated herein by reference in its entirety.

### BACKGROUND OF THE INVENTION

1. Field of the Invention

The present invention relates to a semiconductor device.

2. Description of Related Art

An amount of heat generation of a semiconductor device in which a large electric current flows such as a driving device of an electric vehicle is large. Generally, a semiconductor device having a large amount of heat generation is provided with a cooler.

An external cooler of a related art that uses a refrigerant cannot instantaneously respond to a rapid temperature change of a semiconductor device. For example, Japanese Patent Application No. 2000-174195 (JP 2000-174195 A) discloses a technique according to which even when a travelling state of an electric vehicle or the like that is provided with a semiconductor device rapidly changes and a temperature of an incorporated semiconductor chip rapidly rises, the semiconductor chip can speedily be cooled. The technique, which is different from cooling due to a refrigerant, suppresses a temperature of a semiconductor chip from rising by using a heat of melting of a metal. According to the technique that JP 2000-174195 A discloses, in a semiconductor device that incorporates a semiconductor chip, a surface electrode (emitter electrode, for example) exposed on a surface of the semiconductor chip and an electrode that is extended to the outside of a case of the semiconductor device are connected with a slender metal plate, and an alloy having a low melting point is brought into close contact with the metal plate. When the semiconductor chip generates heat, the heat is transmitted from the surface electrode to the metal plate, further to the low-melting point alloy. The low-melting point alloy absorbs the heat as the heat of melting.

When a semiconductor device is short-circuited, not a temperature rise of an entire semiconductor device, but a local temperature rise of a place where a large electric current flows in the semiconductor device may cause a problem. According to the study of the present inventors, when a semiconductor element is short-circuited between a source and a drain (between collector and emitter), a temperature rapidly rises in a time of an order of several tens of microseconds in an element. For example, during several tens of microseconds, a local temperature can be such high as 1000[° C.]. Although a semiconductor device incorporates a short circuit detection circuit, a time of microsecond is too short for the short circuit detection circuit to operate. If the temperature rise of the semiconductor element (and electrode) can be suppressed during a very short time (several tens of microseconds to 1 millisecond, for example) until the short circuit detection circuit operates, the semiconductor element (and electrode) can be prevented from being damaged since the short circuit detection circuit operates thereafter. However, regarding a rapid temperature rise in such a short time, there is a possibility that by diffusing heat to an outside of the semiconductor element by a refrigerant or a technique such as JP 2000-174195 A, the temperature rise inside of the semiconductor element cannot be sufficiently suppressed. In a semiconductor device manufactured on a semiconductor wafer of silicon carbide, for example, although the heat-resistant temperature of silicon carbide itself is high, a heat-resistant temperature of a metal body or an insulator, which is electrically connected with a layer of silicon carbide, is not such high as that of the silicon carbide. Therefore, in a semiconductor device prepared on a semiconductor wafer of silicon carbide, the semiconductor element (and electrode) is likely to be damaged.

### SUMMARY OF THE INVENTION

The present invention provides a semiconductor device configured to suppress the temperature rise thereof.

A semiconductor device that is an aspect of the present invention includes a first electrode, an endothermic layer and a second electrode. The first electrode is formed on a semiconductor substrate and electrically conductive with an element formed inside of the semiconductor substrate. The endothermic layer is formed on the semiconductor substrate, contacts with the first electrode and has electric conductivity. The second electrode is formed on the semiconductor substrate, contacts with at least one of the first electrode and the endothermic layer, and is soldered to a metal electric conductor. At least one of a work function and contact resistivity of the first electrode is smaller than that of the endothermic layer. A heat of melting of the endothermic layer is larger than that of the first electrode. Solder joinability of the second electrode is higher than that of the endothermic layer.

According to the aspect of the present invention described above, a temperature rise in an order of several tens of microseconds in the semiconductor element (electrode) can be suppressed.

A detail and a further improvement in a technique disclosed in the present specification will be described in following embodiments.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a partial sectional view of a semiconductor device of a first embodiment;

FIG. 2 is a result of simulation of a local temperature distribution during short circuit;

FIG. 3 is a partial sectional view of a semiconductor device of a second embodiment; and

FIG. 4 is a diagram that describes the wettability.

### DETAILED DESCRIPTION OF EMBODIMENTS

At first, an outline of an embodiment of the present invention will be described. A semiconductor device that is an embodiment of the present invention includes a first electrode, a second electrode, and an endothermic layer. The first electrode, the second electrode and the endothermic layer are formed on a semiconductor substrate. The first electrode is directly connected and electrically conductive with an element formed inside of the semiconductor substrate. More specifically, the first electrode is electrically conductive with the element on a surface of the semiconductor substrate. The endothermic layer is in contact with the first electrode. The second electrode is in contact with at least one of the first electrode and the endothermic layer, and is soldered to a metal electric conductor. Herein, the metal electric conductor may be a joining member for electrically joining other device electrically connected to the semiconductor device and the semiconductor device, and typically may be a lead line or a bus bar. The metal electric conductor may be a lead frame.

Relative differences of characteristics of the first electrode, the second electrode and the endothermic layer are as shown below. The first electrode has a work function or contact resistivity smaller than that of the endothermic layer. The endothermic layer has a heat of melting larger than that of the first electrode. The second electrode has the solder joinability higher than that of the endothermic layer. When expressed more accurately, it is prerequisite that a metal material that forms each of the first electrode, the second electrode and the endothermic layer has the characteristics described above. However, in place of the expression that “a metal material that forms the first electrode has a work function or contact resistivity smaller than that of a metal material forming the endothermic layer”, an expression that “a first electrode has a work function or contact resistivity smaller than that of the endothermic layer” will be used hereinafter in order to simplify the explanation.

In more detail, the contact resistivity means the resistivity determined in consideration of a barrier height when the electrode or the endothermic layer is silicidized. The silicidation means for a metal of the electrode or the endothermic layer to combine with silicon of the semiconductor substrate to form a compound. Hereinafter, in all cases where the resistivity is expressed as the “contact resistivity”, it means the resistivity determined in consideration of a barrier height when the electrode or endothermic layer is silicidized. Metals having smaller contact resistivity include nickel (Ni), titanium (Ti), tungsten (W), and so on. The contact resistivities of these metals are known to be smaller than the contact resistivity of beryllium described below. Further, the work function of each of aluminum and titanium is 4.13 [eV] and 4.14 [eV], respectively, and is known to be smaller than the work function of beryllium described below (5.0 [eV]).

A semiconductor device of the related art includes a first electrode and a second electrode. The first electrode is an electrode that directly contacts and is electrically conductive with a semiconductor element, and the second electrode is an electrode that contacts with other device, or a metal plate such as a lead frame. The second electrode contacts with the lead frame via a bonding wire in some cases. Since the first electrode directly contacts and is electrically conductive with the semiconductor element, compared with the second electrode or the endothermic layer, a material having the smallest work function or contact resistivity to a surface of the semiconductor element is selected. In more detail, the work function or the contact resistivity of the first electrode may be smaller than that of the endothermic layer and equal to or smaller than that of the second electrode. In other words, the first electrode has an ohmic property higher than that of the endothermic layer. Further, the ohmic property of the first electrode is equal to or higher than that of the second electrode.

On the other hand, since the second electrode is an electrode that electrically connects an external device and the semiconductor device, the second electrode is attached to a metal conductive material with a solder material. The second electrode has the solder joinability better than those of the first electrode and the endothermic layer. In more detail, as the second electrode, a material that has the solder joinability better than that of the endothermic layer and equal to or better than that of the first electrode is selected. The solder joinability can be quantitatively evaluated by the “wettability”, for example. “The wettability” shows how large an area a melted solder comes into contact with a member that is a target to be joined. “The wettability” can be expressed by an angle formed by a tangential line to a melted solder in a periphery of the melted solder and a surface of a target member to be joined when the melted solder is dropped on a surface of the target member to be joined.

A material of the first electrode may be the same as that of the second electrode. The material of the first electrode and the second electrode may be typically aluminum, copper or nickel. In a case where the material of the first electrode is the same as that of the second electrode, the first electrode may be assumed to have the work function or the contact resistivity smaller than that of the endothermic layer. Alternatively, the second electrode may be assumed to have the solder joinability larger than that of the endothermic layer. Still further, the endothermic layer may be assumed to have the heat of melting larger than that of the first electrode.

The endothermic layer which is not installed in the semiconductor device of the related art is a metal body that is installed to absorb heat of the semiconductor device. Therefore, the heat of melting of the endothermic layer is preferable to be larger than that of the first electrode, further preferable to be larger than those of the first electrode and the second electrode. Since the endothermic layer needs to start melting at a temperature lower than other electrodes and to absorb the heat of the semiconductor element as the heat of melting, the melting point of the endothermic layer is lower than those of other electrodes. A material of the endothermic layer may be typically beryllium.

The semiconductor device described above includes the first electrode, the second electrode and the endothermic layer, which are formed according to a semiconductor process. Typically, on the semiconductor substrate, the first electrode, the endothermic layer and the second electrode may be stacked in this order, and an entire thickness thereof may be several tens of micrometers. By disposing the endothermic layer having large heat of melting in such a proximate distance, heat locally generated in short time when the semiconductor element is short-circuited can be rapidly absorbed, as a result, a local temperature rise can be effectively suppressed. In the embodiment of the present invention, it is preferable that the first electrode and the endothermic layer contact within several tens of micrometers (within 50 μm if possible) from a contact site of the element of the semiconductor substrate and the first electrode.

The embodiment of the present invention is particularly effective in a semiconductor device that uses a silicon carbide substrate. While an ordinary silicon base semiconductor substrate has a heat-resistant temperature of about 300[° C.], the heat-resistant temperature of a silicon carbide base semiconductor substrate is about 1500[° C.]. On the other hand, a local temperature during short-circuiting may exceed 1000[° C.]. At such a temperature, in the silicon base semiconductor substrate, the substrate itself may be damaged. On the other hand, in the case of the silicon carbide base semiconductor substrate, although the substrate is damaged less, the electrode is largely damaged. In the embodiment of the present invention, by disposing the endothermic layer, which has the melting point lower than that of the first electrode and the heat of melting (heat content) larger than that of the first electrode, within 50 μm from the contact point between the semiconductor element and the first electrode, the first electrode can be suppressed from rising in the temperature. Thus, the thermal influence which the first electrode receives is reduced.

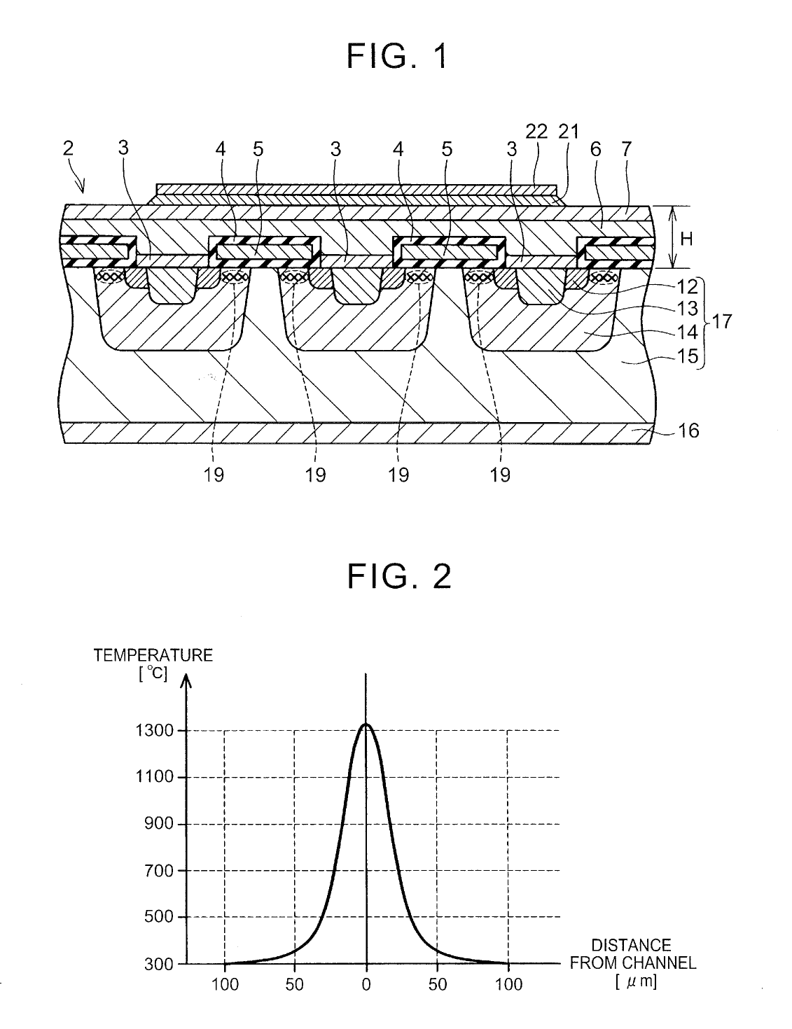

By referring to the drawings, a semiconductor device 2 of the first embodiment will be described. FIG. 1 shows a partial cross-sectional view of the semiconductor device 2. The semiconductor device 2 is a MOS transistor. A semiconductor substrate 17 is made of silicon carbide (SiC). On a lower surface of the semiconductor substrate 17, a drain electrode 16 is formed. In the semiconductor substrate 17, from a lower side of FIG. 1, an n-type drift layer 15, a p-type body region 14, a p⁺-type contact region 13 and an n⁺-type source region 12 are formed. These layers and regions form a MOS transistor. In FIG. 1, although some of source regions 12, contact regions 13 and body regions 14 are drawn, reference numerals are given to only those in the most right side region and omitted in the others. Since a structure of the MOS transistor is well known, a detailed description is omitted.

On a superficial layer of the semiconductor substrate 17 (an upper side of the semiconductor substrate 17 in FIG. 1), some of the electrodes and layers are formed. An insulating layer 4 is formed over abutting source regions 12 with the drift layer 15 sandwiched therebetween. In the insulating layer 4, a gate electrode 5 is formed so as to face the drift layer 15 between abutting source regions 12. Further, a contact electrode 3 is formed so as to come into contact with a surface of the contact region 13 and also come into partial contact with a surface of the source region 12 located on both sides of the contact regions 13. The endothermic layer 6 is farmed so as to come into contact with the contact electrode 3 and to cover the insulating layer 4. A source electrode 7 is formed on the uppermost layer so as to cover an entirety of the endothermic layer 6. The endothermic layer 6 has electric conductivity. Therefore, the contact electrode 3 and the source electrode 7 respectively in contact with both sides of the endothermic layer 6 are electrically conductive with each other. On a surface of the source electrode 7 an electrode plate 22 is fixed via a solder 21. A source of the MOS transistor is connected with an external device via the electrode plate 22.

Except for the endothermic layer 6, an arrangement of other electrodes is the same as the electrode arrangement that a conventional semiconductor device has. That is, one of the features of the semiconductor device 2 of the first embodiment is that the endothermic layer 6 is sandwiched between the conventional contact electrode 3 and the source electrode 7.

As is well known, the contact electrode 3 and the source electrode 7 are formed in a step of a semiconductor process for forming a semiconductor element. The endothermic layer 6 is different only in material from the contact electrode 3 and the source electrode 7 and a method of manufacturing thereof is roughly the same as that of these electrodes. That is, also the endothermic layer 6 can be formed in a step of a semiconductor process the same as that of the contact electrode 3 and so on. A preferable thickness of the contact electrode 3 is 1 to 2 [μm], and preferable thicknesses of the endothermic layer 6 and the source electrode 7 are 4 to 5 [μm]. Therefore, a total thickness of the electrode layers obtained by combining thicknesses of the contact electrode 3, the endothermic layer 6 and the source electrode 7 (a distance shown by a reference mark H in FIG. 1) is about 10 [μm].

Difference between characteristics of the contact electrode 3, the source electrode 7 and the endothermic layer 6 will be described. The contact electrode 3 directly contacts with the semiconductor substrate 17. The contact electrode 3 is preferable to come into ohmic contact with the semiconductor substrate 17. As an index to quantitatively express the ohmic property, there is a work function or contact resistivity. The contact electrode 3 is preferable to be a metal having small work function or contact resistivity. Herein, the contact electrode 3, the source electrode 7 or the endothermic layer 6 combines with silicon of the semiconductor substrate to form a compound, that is, silicidized. Therefore, the contact resistivity thereof is regarded as the resistivity determined in consideration of a barrier height when the contact electrode 3, the source electrode 7 or the endothermic layer 6 is silicidized. The resistivity determined in consideration of the barrier height will be described below. Specifically, a material of the contact electrode 3 is desirable to be nickel, aluminum, titanium or alloys thereof. Further, the work functions of aluminum and titanium are 4.13 [eV] and 4.14 [eV], respectively, and are known to be lower than the work function of beryllium (5.0 [eV]) described below.

The source electrode 7 is connected with the electrode plate 22 via the solder 21. Therefore, the source electrode 7 is desirable to have high joinability with a solder material. As a material of the source electrode 7, typically, aluminum or nickel can be used. As an index that quantitatively expresses the joinability with the solder material, “wettability” can be used. The “wettability” will be described below.

The endothermic layer 6 is provided to absorb heat of the contact electrode 3 when a temperature of the contact electrode 3 rises due to heat generation of the semiconductor element. As the endothermic layer 6, a material having the heat of melting larger than that of the contact electrode 3 or the source electrode 7 is used. Typically, the endothermic layer 6 is made of beryllium. The heat of melting of beryllium is 1354.0 [J/g] and far larger than the heat of melting of aluminum (397.0 [J/g]) or the heat of melting of nickel (300.0 [J/g]).

When relative characteristics differences of the contact electrode 3, the source electrode 7 and the endothermic layer 6 are summarized, these are as shown below. The contact electrode 3 has smaller work function or contact resistivity than that of the endothermic layer 6. The endothermic layer 6 has the heat of melting larger than those of the contact electrode 3 and the source electrode 7. The source electrode 7 has the solder joinability higher than that of the endothermic layer 6 (the solder joinability of the source electrode 7 is good).

An advantage of the endothermic layer 6 will be described. In FIG. 1, a region between the source region 12 and the drift layer 15 in a superficial layer of the body region 14 (a region shown with a mark 19) is called a channel, and when a voltage is applied to the gate. An electric current flows to the channel 19. When the element is short-circuited, a large electric current flows to the channel 19 and the channel 19 rapidly generates heat. For example, in a transistor that is used in a drive system of an electric vehicle, during normal operation, an inductor L is about 1.0 [mH] and a voltage is about 500 [V]. An electric current that flows to the channel 19 is an order of about V/L=0.5 [A/μsec]. However, when the transistor is short-circuited, a level of the inductor L becomes 1.0 [pH]. Thus, an electric current that flows to the channel 19 becomes an order of V/L=500 [A/μsec]. That is, roughly instantaneously, 500 [A] flows to the channel 19. The electric current instantaneously generates heat. Although a short circuit detection circuit is incorporated in a semiconductor device, a time of microseconds is too short for the short circuit detection circuit to operate. Therefore, when the temperature rise in the semiconductor element (and electrode) can be suppressed from occurring until a time when the short circuit detection circuit operates (several tens of microseconds to several milliseconds, for example), the semiconductor element (and electrode) can be avoided from being damaged.

A result of simulation of a temperature distribution when the electric current described above assumed to flow to the channel 19 for several tens of microseconds is shown in FIG. 2. A graph in FIG. 2 shows a temperature distribution immediately after the electric current flowed to the channel 19 for several tens of microseconds. In a horizontal axis, [0] shows a position of the channel 19. A left side from the position of the channel 19 (position of [0]) shows a distance toward an electrode and a right side shows a distance toward a depth direction of the element. A vertical axis shows a temperature. That is, when the short circuit occurs, the channel 19 instantaneously rises to 1300[° C.] and a temperature at a position distanced by about 20 [μm] from the channel 19 becomes about 900[° C.]. A temperature at a position distanced by about 50 [μm] is about 350[° C.]. The contact electrode 3 is located in the proximity of the channel 19 and has a thickness of about 1.0 [μm]. That is, when the transistor element is short-circuited, the temperature of the channel 19 instantaneously (during several microseconds to several tens of microseconds) rises to 1300[° C.] and also the temperature of the contact electrode 3 rises to 900[° C.] or more. Although the substrate of the semiconductor device 2 is silicon carbide and can endure up to about 1500[° C.], the metal used in the electrode is melted. For example, the melting point of aluminum is 660[° C.].

Here, in the semiconductor device 2 of the embodiment, the contact electrode 3 contacts with the endothermic layer 6. Moreover, since a thickness of the contact electrode 3 is about 1.0 [μm], the heat generated in the channel 19 passes through the contact electrode 3 and is immediately absorbed by the endothermic layer 6. That is, the endothermic layer 6 suppresses the temperature of the contact electrode 3 from rising during short-circuiting.

Further, the source electrode 7 is stacked on the endothermic layer 6. Since an amount of heat of the channel 19 is stored in the endothermic layer 6, the source electrode 7 is thermally protected. Thus, the endothermic layer 6 thermally protects the contact electrode 3 and the source electrode 7 from heat generation in a period of about several tens of microseconds during short-circuiting.

It is general that the semiconductor device includes the short circuit detection circuit so that the electric current is immediately interrupted when the short-circuiting is detected. A response time of the short circuit detection circuit is about several hundreds of microseconds to several milliseconds. Therefore, when the endothermic layer 6 can suppress a local electrode temperature rise at a position near the semiconductor substrate during several hundreds of microseconds immediately after the short circuit, the short circuit detection device interrupts the electric current after that. Thus, the semiconductor device is not severely damaged. Since various techniques have been proposed regarding the short circuit detection devices, detailed description thereof will be omitted here.

Examples of the materials of the contact electrode 3, the source electrode 7 and the endothermic layer 6 will be cited. In one example, the contact electrode 3 is made of aluminum, and the endothermic layer 6 is made of beryllium. The contact resistivity of aluminum is known to be smaller than the contact resistivity of beryllium. Alternatively, as was described above, the work function of aluminum (4.13 [eV]) is smaller than the work function of beryllium (5.0 [eV]). Therefore, both of the contact resistivity and work function of the contact electrode 3 made of aluminum is lower than both of those of the endothermic layer 6 made of beryllium. Further, the heat of melting of aluminum is 397.0 [J/g] and the heat of melting of beryllium is 1354.0 [J/g]. That is, the endothermic layer 6 has the heat of melting larger than that of the contact electrode 3. The source electrode 7 may be aluminum, nickel or copper. The solder joinability of these materials is known to be higher than the solder joinability of beryllium.

In another embodiment, the contact electrode 3 is formed of nickel and the endothermic layer 6 is formed of beryllium. The contact resistivity of nickel is also known to be lower than the contact resistivity of beryllium. Further, the melting point of nickel is 1450[° C.] and the melting point of beryllium is 1280[° C.]. Therefore, in this embodiment, the endothermic layer 6 has the melting point lower than that of the contact electrode 3. Further, the heat of melting of nickel is 300.0 [J/g] and the heat of melting of beryllium is 1354.0 [J/g]. That is, the endothermic layer 6 has the heat of melting larger than that of the contact electrode 3. In this embodiment, before the contact electrode made of nickel is melted, the endothermic layer 6 made of beryllium starts melting and absorbs the heat of melting. Since a melting and endothermic reaction is generated instantaneously, the temperature rise of the contact electrode 3 in a very short time (a time of order of several tens of microseconds) immediately after the short-circuiting of the semiconductor element can be suppressed. When elapsed about 1 millisecond, since a controller that manages the semiconductor device detects the short circuit and cut the electric current, the contact electrode 3 is protected from damage due to the heat. The source electrode 7 may be aluminum, nickel or copper.

Further, in still another embodiment, the contact electrode 3 is made of titanium, and the endothermic layer 6 is made of beryllium. The work function of titanium (4.14 [eV]) is smaller than the work function of beryllium (5.0 [eV]). Therefore, the work function of the contact electrode 3 is smaller than the work function of the endothermic layer 6. Further, the melting point of titanium is 1660[° C.] and the melting point of beryllium is 1280[° C.]. Therefore, in this embodiment, the endothermic layer 6 has the melting point lower than that of the contact electrode 3. Further, the heat of melting of titanium is 389.0 [J/g] and the heat of melting of beryllium is 1354.0 [J/g]. That is, the endothermic layer 6 has the heat of melting larger than that of the contact electrode 3. Similarly as the case of nickel, also in this embodiment, before the contact electrode 3 made of titanium melts, the endothermic layer 6 made of beryllium starts melting and absorbs the heat of melting. The temperature rise of the contact electrode 3 in a very short time (a time of order of several tens of microseconds) immediately after the short-circuiting of the semiconductor element can be suppressed. The source electrode 7 may be aluminum, nickel or copper.

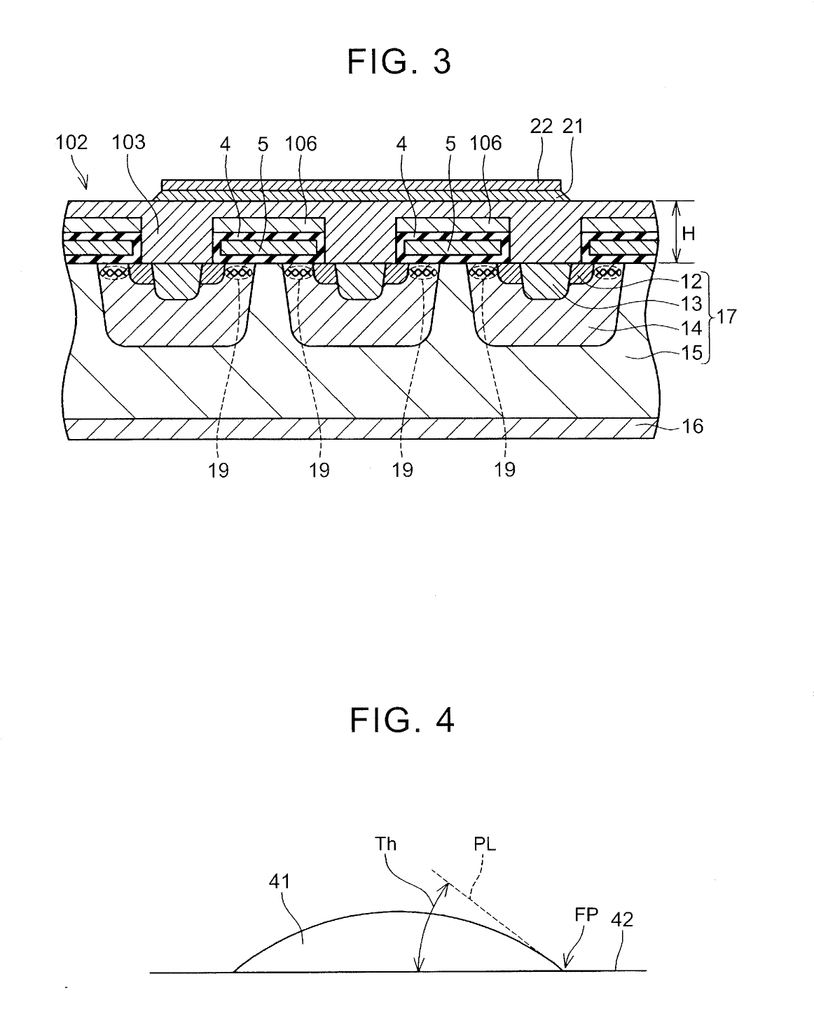

Next, a semiconductor device 102 of the second embodiment will be described. FIG. 3 shows a partially enlarged sectional view of the semiconductor device 102. Different points from the semiconductor device 2 of the first embodiment are in that a contact electrode and a source electrode are integrated and an endothermic layer 106 is formed on an insulating layer 4 that covers a gate electrode 5. In the second embodiment, an electrode obtained by integrating the contact electrode and the source electrode is called a contact/source electrode 103. The endothermic layer 106 is in contact with the contact/source electrode 103. Since a structure of the semiconductor substrate 17 is the same as the case of the first embodiment, the description thereof is omitted.

In the case of the second embodiment, differences of relative characteristics of the contact/source electrode 103 and the endothermic layer 106 are as shown below. The contact/source electrode 103 has the work function or contact resistivity smaller than that of the endothermic layer 106. The endothermic layer 106 has the heat of melting larger than that of the contact/source electrode 103. The contact/source electrode 103 has the solder joinability higher than that of the endotheimic layer 106. Also the semiconductor device 102 of the second embodiment, similarly as the semiconductor device 2 of the first embodiment, can suppress a rapid temperature rise of the contact/source electrode 103 for several tens of microseconds during the short circuit.

The contact resistivity will be described. As described above, the contact resistivity in the present specification means the resistivity determined in consideration of a barrier height in silicidized metal. The resistivity determined in consideration of the barrier height (contact resistivity) is given by the following formula (1). In the formula (1), φ_{b} corresponds to barrier height, mₙ corresponds to effective mass of an electron, mₚ corresponds to effective mass of hole, n corresponds to electron density in a contact interface of n⁺ region, p corresponds to hole density in a contact interface of p⁺ region, and h corresponds to Plank constant.

$$Rc ∝ exp [ \frac{4 \sqrt{( {m}_{n} or {m}_{p} ) {ɛ}_{s}}}{h} ( \frac{{φ}_{b}}{\sqrt{n or p}} ) ] \qquad ( 1 )$$

When characteristic values of nickel, titanium, tungsten and beryllium, which were described above are substituted in the formula (1) described above, and the contact resistivity is obtained, it can be confirmed that the contact resistivities of nickel, titanium and tungsten are smaller than the contact resistivity of beryllium. Regarding the formula (1) described above, please see Hiroaki Tanaka, Takehiro Isogai, Rihito Kuroda, Yukihisa Nakao, Tomoyuki Suwa, Tetsuya Goto, Akinobu Teramoto, Shigetoshi Sugawa, and Tadahiro Ohmi, “Technique for forming low barrier height low resistance contact for high performance transistor”, Proceedings of 20^{th} Microelectronics Conference, pp 32 to 39, 2008, in which more detail is described.

Next, the “wettability” that is one of indexes of the solder joinability will be described with reference to FIG. 4. The “wettability” is, as shown in FIG. 4, evaluated by a contact angle Th when a melted solder material 41 is placed on a host material 42. The contact angle is an angle formed by a tangential line PL of the solder material and a surface of the host material 42 immediately below the solder material form. The tangential line PL is a tangential line at a boundary FP of the solder material 41 on a surface of the host material. It expresses that the smaller the contact angle is, the higher the wettability is.

As the index that quantitatively expresses the solder joinability, other than the “wettability” described above, a tensile strength when two host materials are joined with a solder, pulled in opposite direction each other, and the solder is broken may be used.

Points of attention regarding the semiconductor devices 2 and 102 described in the embodiments will be described. A MOS transistor that is formed with the n-type drift layer 15, p-type body region 14, p+-type contact region 13 and n+-type source region 12 formed on the semiconductor substrate 17 may be regarded as one of examples of the semiconductor elements. The technique disclosed in the present invention is not limited to the MOS transistor. The technique may be applied to a semiconductor device in which a vertical (trench-type) semiconductor element, a diode or other elements are formed on the semiconductor substrate.

In the first embodiment, the contact electrode 3 that directly contacts with the semiconductor substrate 17 may be regarded as the first electrode. Further, the source electrode 7 to which the electrode plate 22 is joined via the solder 21 may be regarded as the second electrode. In the second embodiment, the contact/source electrode 103 may be regarded as the first electrode and the second electrode made of the same material.

The embodiments of the present invention are particularly suitable for semiconductor devices that use a semiconductor substrate which has silicon carbide having a high heat-resistant temperature as a base.

In the above, although specific embodiments of the present invention were detailed, these are only illustrations. In the present invention, various modifications and alterations of the specific embodiments illustrated above are included. The technical elements described in the present specification and the drawings can exhibit technical usefulness singularly or in various combinations thereof.

What is claimed is:

1. A semiconductor device comprising:
a first electrode that is formed on a semiconductor substrate and electrically conductive with an element formed inside of the semiconductor substrate;
an endothermic layer that is formed on the semiconductor substrate, contacts with the first electrode and has electric conductivity; and
a second electrode that is formed on the semiconductor substrate, in contact with at least one of the first electrode and the endothermic layer, and soldered to a metal electric conductor, wherein
at least one of a work function and contact resistivity of the first electrode is smaller than that of the endothermic layer,
a heat of melting of the endothermic layer is larger than that of the first electrode, and
solder joinability of the second electrode is higher than that of the endothermic layer.

2. The semiconductor device according to claim 1, wherein a melting point of the endothermic layer is lower than that of the first electrode.

3. The semiconductor device according to claim 1, wherein the first electrode is made of a material equal to a material which the second electrode is made of.

4. The semiconductor device according to claim 1, wherein the endothermic layer is made of beryllium.

5. The semiconductor device according to claim 1, wherein the first electrode, the endothermic layer, and the second electrode are stacked in this order from a side near the semiconductor substrate.

6. The semiconductor device according to claim 1, wherein the first electrode and the endothermic layer are in contact at a distance within 50 pm from a contact site of the element and the first electrode.
